(19) United States
(12) Patent Application Publication
(10) Pub. No.: US 2023/0087984 A1
(43) Pub. Date: Mar. 23, 2023

(54) SILICA-BASED SLURRY COMPOSITIONS CONTAINING HIGH MOLECULAR WEIGHT POLYMERS FOR USE IN CMP OF DIELECTRICS

(71) Applicant: CMC Materials, Inc., Aurora, IL (US)

(72) Inventors: Brian REISS, Woodridge, IL (US); Brittany JOHNSON, Oak Park, IL (US); Sajo NAIK, Naperville, IL (US); Lung-Tai LU, Tainan City (TW); Kim LONG, Naperville, IL (US); Elliot KNAPTON, Aurora, IL (US); Douglas ROBELLO, Webster, NY (US); Sarah BROSNAN, St. Charles, IL (US)

(21) Appl. No.: 17/951,288

(22) Filed: Sep. 23, 2022

Related U.S. Application Data
(60) Provisional application No. 63/247,429, filed on Sep. 23, 2021.

(51) Int. Cl. C09G 1/02; H01L 21/306; H01L 21/321

(52) U.S. Cl. CPC C09G 1/02; H01L 21/30625; H01L 21/3212

(57) ABSTRACT

The invention provides a chemical-mechanical polishing composition comprising: (a) about 3.0 wt. % to about 10 wt. % silica abrasive; (b) an anionic polymer having a weight average molecular weight of about 400 kDa to about 7000 kDa; and (c) water, wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12. The invention additional provides a chemical-mechanical polishing composition comprising: (a) about 3.0 wt. % to about 10 wt. % silica abrasive; (b) a nonionicpolymer having a weight average molecular weight of about 300 kDa to about 7000 kDa; and (c) water, wherein the polishing composition has a viscosity of at least about 2 cPs, and a pH of about 9 to about 12. The invention also provides a method of chemically-mechanically polishing a substrate, especially a substrate comprising silicon oxide, silicon nitride, polysilicon, or combinations thereof, using said compositions.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

As the size of integrated circuits is reduced and the number of integrated circuits on a chip increases, the components that make up the circuits must be positioned closer together in order to comply with the limited space available on a typical chip. Effective isolation between circuits is important for ensuring optimum semiconductor performance. To that end, shallow trenches are etched into the semiconductor substrate and filled with insulating material to isolate active regions of the integrated circuit. For example, shallow trench isolation (STI) is a process in which a silicon nitride layer is formed on a silicon substrate, shallow trenches are formed via etching or photolithography, and a dielectric layer is deposited to fill the trenches. Due to variation in the depth of trenches formed in this manner, it is typically necessary to deposit an excess of dielectric material on top of the substrate to ensure complete filling of all trenches. The dielectric material (e.g., a silicon oxide) conforms to the underlying topography of the substrate.

Thus, after the dielectric material has been placed, the surface of the deposited dielectric material is characterized by an uneven combination of raised areas of the dielectric material separated by trenches in the dielectric material, the raised areas and trenches of the dielectric material aligning with corresponding raised areas and trenches of the underlying surface. The region of the substrate surface that includes the raised dielectric material and trenches is referred to as a pattern field of the substrate, e.g., as “pattern material,” “pattern oxide,” or “pattern dielectric.” The pattern field is characterized by a “step height,” which is the difference in height of the raised areas of the dielectric material relative to the trench height.

The excess dielectric material is typically removed by a CMP process, which additionally provides a planar surface for further processing. During removal of the raised area material, an amount of material from the trenches also will be removed. This removal of material from the trenches is referred to as “trench erosion” or “trench loss.” Trench loss is the amount (thickness, e.g., in Angstroms (Å)) of material removed from trenches in achieving planarization of pattern dielectric material by eliminating an initial step height. Trench loss is calculated as the initial trench thickness minus a final trench thickness. Desirably, the rate of removal of material from trenches is well below the rate of removal from raised areas. Thus, as material of the raised areas is removed (at a faster rate compared to material being removed from the trenches) the pattern dielectric becomes a highly planarized surface that may be referred to as a “blanket” region of the processed substrate surface, e.g., “blanket dielectric” or “blanket oxide.”

A polishing composition can be characterized according to its polishing rate (i.e., removal rate) and its planarization efficiency. The polishing rate refers to the rate of removal of a material from the surface of the substrate and is usually expressed in terms of units of length (thickness, e.g., in Angstroms (Å)) per unit of time (e.g., per minute). Different removal rates relating to different regions of a substrate, or to different stages of a polishing step, can be important in assessing process performance. A “pattern removal rate” or “active removal rate” is the rate of removal of dielectric material from raised areas of pattern dielectric layer at a stage of a process during which a substrate exhibits a substantial step height. “Blanket removal rate” refers to a rate of removal of dielectric material from planarized (i.e., “blanket”) areas of a pattern dielectric layer at an end of a polishing step, when step height has been significantly (e.g., essentially entirely) reduced. Planarization efficiency relates to step height reduction versus amount of material removed from the substrate (i.e., step height reduction divided by trench loss). Specifically, a polishing surface, e.g., a polishing pad, first contacts the “high points” of the surface and must remove material in order to form a planar surface. A process that results in achieving a planar surface with less removal of material is considered to be more efficient than a process requiring removal of more material to achieve planarity.

Often the rate of removal of a pattern material can be rate-limiting for the dielectric polishing step in STI processes, and therefore high removal rates are desired to increase device throughput. However, generally, high abrasive (e.g., colloidal silica) loadings are necessary to achieve high removal rates. Thus, conventionally used polishing compositions, containing high abrasive (e.g., colloidal silica) loadings have been prohibitively costly.

Thus, a need remains for self-stopping CMP compositions and methods for chemical-mechanical polishing that can exhibit high removal rates of a pattern material without necessitating high abrasive (e.g., colloidal silica) loadings.

The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) about 0.001 wt. % to about 10 wt. % silica abrasive; (b) an anionic polymer having a weight average molecular weight of about 400 kDa to about 7,000 kDa; and (c) water, wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12.

The invention also provides a chemical-mechanical polishing composition comprising: (a) about 0.001 wt. % to about 10 wt. % silica abrasive; (b) a nonionic polymer having a weight average molecular weight of about 300 kDa to about 7,000 kDa; and (c) water, wherein the polishing composition has a viscosity of at least about 1.2 cPs, and a pH of about 9 to about 12.

The invention further provides a method of chemically-mechanically polishing a substrate comprising: (i) providing a substrate, (ii) providing a polishing pad, (iii) providing a chemical-mechanical polishing composition comprising: (a) about 0.001 wt. % to about 10 wt. % silica abrasive; (b) an anionic polymer having a weight average molecular weight of about 400 kDa to about 7,000 kDa; and (c) water, wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The invention still further provides a method of chemically-mechanically polishing a substrate comprising: (i) providing a substrate, (ii) providing a polishing pad, (iii) providing a chemical-mechanical polishing composition comprising: (a) about 0.001 wt. % to about 10 wt. % silica abrasive; (b) a nonionic polymer having a weight average molecular weight of about 300 kDa to about 7,000 kDa; and (c) water, wherein the polishing composition has a viscosity of at least about 1.2 cPs and a pH of about 9 to about 12, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### BRIEF DESCRIPTION OF THE DRAWINGS

FIG. 1 is a plot showing the TEOS removal rate (Å/min) as a function of dynamic light scattering (DLS) particle size (nm) for a polishing composition containing 8 wt. % silica abrasive and 1000 ppm of a polyacrylic acid polymer having a weight average molecular weight of about 450 kDa, as compared to a control polishing composition not containing a polymer, as described in Example 1.

FIG. 2A is a plot showing the TEOS removal rate (Å/min) as a function of polyacrylic acid polymer molecular weight (Da) for a polishing composition containing 3 wt. % silica abrasive or 5 wt. % silica abrasive, as described in Example 3.

FIG. 2B is a plot showing the SiN removal rate (Å/min) as a function of polyacrylic acid polymer molecular weight (Da) for a polishing composition containing 3 wt. % silica abrasive or 5 wt. % silica abrasive, as described in Example 3.

FIG. 3 is a plot showing the TEOS removal rate (Å/min) as a function of polishing composition viscosity (cPs) for a polishing composition containing 3 wt. % silica abrasive or 5 wt. % silica abrasive, as described in Example 3.

FIG. 4A is a plot showing the viscosity (cPs) as a function of polymer molecular weight (kDa) for a polishing composition containing 3 wt. % silica abrasive, as described in Example 3.

FIG. 4B is a plot showing the TEOS removal rate (Å/min) as a function of polymer molecular weight (kDa) for a polishing composition containing 3 wt. % silica abrasive, as described in Example 3.

FIG. 5 is a plot showing the viscosity (cPs) as a function of silica abrasive loading (wt. %) for a polishing composition containing a polyacrylic acid polymer having a weight average molecular weight of about 800 kDa, as compared to a control polishing composition not containing a polymer, as described in Example 6.

FIG. 6A is a plot showing the TEOS removal rate (Å/min) as a function of silica abrasive loading (wt. %) for a polishing composition containing a polyacrylic acid polymer having a weight average molecular weight of about 800 kDa, as compared to a control polishing composition not containing a polymer, as described in Example 6.

FIG. 6B is a plot showing the SiN removal rate (Å/min) as a function of silica abrasive loading (wt. %) for a polishing composition optionally containing a polyacrylic acid polymer having a weight average molecular weight of about 800 kDa, as described in Example 6.

FIG. 6C is a plot showing the TEOS removal rate (Å/min) as a function of viscosity (cPs) for a polishing composition containing a polyacrylic acid polymer having a weight average molecular weight of about 800 kDa, as compared to a control polishing composition not containing a polymer, as described in Example 6.

FIG. 6D is a plot showing the SiN removal rate (Å/min) as a function of viscosity (cPs) for a polishing composition containing a polyacrylic acid polymer having a weight average molecular weight of about 800 kDa, as compared to a control polishing composition not containing a polymer, as described in Example 6.

### DETAILED DESCRIPTION OF THE INVENTION

The invention provides a chemical-mechanical polishing composition comprising, consisting essentially of, or consisting of: (a) about 0.001 wt. % to about 10 wt. % silica abrasive; (b) an anionic polymer having a weight average molecular weight of about 400 kDa to about 7,000 kDa; and (c) water, wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12. Additionally, the invention provides a chemical-mechanical polishing composition comprising, consisting essentially of, or consisting of: (a) about 0.001 wt. % to about 10 wt. % silica abrasive; (b) a nonionic polymer having a weight average molecular weight of about 300 kDa to about 7,000 kDa; and (c) water, wherein the polishing composition has a viscosity of at least about 1.2 cPs and a pH of about 9 to about 12.

The polishing composition comprises a silica abrasive. As used herein, the terms “silica abrasive,” “silica abrasive particle,” “silica particle,” and “abrasive particle” can be used interchangeably, and can refer to any silica particle (e.g., colloidal silica particle). The silica particle (e.g., colloidal silica particle) can be modified (e.g., surface modified) or unmodified, and have a negative native zeta potential or a positive native zeta potential. As used herein, the phrase “native zeta potential” refers to the zeta potential of the silica abrasive prior to adding the silica abrasive to the polishing composition. For example, the native zeta potential can refer to the zeta potential of a silica abrasive prior to adding the silica abrasive to the polishing composition as measured in a neutral (i.e., pH of about 7) aqueous solution. A skilled artisan will be able to determine whether the silica abrasive, prior to adding the silica abrasive to the polishing composition, has a negative native zeta potential or a positive native zeta potential. The charge on dispersed particles such as a silica abrasive (e.g., colloidal silica particles) is commonly referred to as the zeta potential (or the electrokinetic potential). The zeta potential of a particle refers to the electrical potential difference between the electrical charge of the ions surrounding the particle and the electrical charge of the bulk solution of the composition in which it is measured (e.g., the liquid carrier and any other components dissolved therein). The zeta potential is typically dependent on the pH of the aqueous medium. For a given polishing composition, the isoelectric point of the particles is defined as the pH at which the zeta potential is zero. As the pH is increased or decreased away from the isoelectric point, the surface charge (and hence the zeta potential) is correspondingly decreased or increased (to negative or positive zeta potential values). The native zeta potential and the zeta potential of the polishing composition may be obtained using the Model DT-1202 Acoustic and Electro-acoustic spectrometer available from Dispersion Technologies, Inc. (Bedford Hills, N.Y.). As used herein, the phrase “negative zeta potential” refers to a silica abrasive that exhibits a negative surface charge when measured in the polishing composition. As used herein, the phase “positive zeta potential” refers to a silica abrasive that exhibits a positive surface charge when measured in the polishing composition.

In some embodiments, the silica abrasive has a zeta potential of less than 0 mV when measured in the polishing composition, i.e., the silica abrasive has a negative zeta potential when measured in the polishing composition. For example, the silica abrasive can have a zeta potential of −10 mV or less in the chemical-mechanical polishing composition, a zeta potential of −20 mV or less in the chemical-mechanical polishing composition, a zeta potential of −30 mV or less in the chemical-mechanical polishing composition, or a zeta potential of −40 mV or less in the chemical-mechanical polishing composition. In some embodiments, the silica abrasive has a negative zeta potential of from about 0 mV to about −60 mV, e.g., from about −10 mV to about −60 mV, from about −10 mV to about −50 mV, from about −10 mV to about −40 mV, from about −20 mV to about −60 mV, from about −20 mV to about −50 mV, from about −20 mV to about −40 mV, from about −30 mV to about −40 mV, or from about −20 mV to about −30 mV.

The silica abrasive (e.g., colloidal silica particle) can be modified (e.g., surface modified) or unmodified, and have a negative native zeta potential or a positive native zeta potential. Thus, the silica abrasive (e.g., colloidal silica particle) can have a positive zeta potential or a negative zeta potential prior to addition to the chemical-mechanical polishing composition. For example, the silica particle (e.g., colloidal silica particle) can have a native zeta potential of less than 0 mV (e.g., −5 mV, or lower) prior to addition to the chemical-mechanical polishing composition. Alternatively, the silica particle (e.g., colloidal silica particle) can have a native zeta potential of 0 mV or more (e.g., 5 mV, or more) prior to addition to the chemical-mechanical polishing composition.

Silica particles (e.g., colloidal silica particles) can be prepared by various methods, some examples of which are commercially used and known. Useful silica particles include precipitated or condensation-polymerized silica, which may be prepared using known methods, such as by methods referred to as the “sol gel” method or by silicate ion-exchange. Condensation-polymerized silica particles are often prepared by condensing Si(OH)₄ to form substantially spherical (e.g., spherical, ovular, or oblong) particles. The precursor Si(OH)₄ may be obtained, for example, by hydrolysis of high purity alkoxysilanes, or by acidification of aqueous silicate solutions. U.S. Pat. No. 5,230,833 describes a method for preparing colloidal silica particles in solution.

In some embodiments, the silica abrasive is colloidal silica. As known to one of ordinary skill in the art, colloidal silicas are suspensions of fine amorphous, nonporous and typically spherical particles in a liquid phase. The colloidal silica can take the form of condensation-polymerized or precipitated silica particles. In some embodiments, the silica is in the form of wet-process type silica particles. The particles, e.g., colloidal silica, can have any suitable average size (i.e., average particle diameter). If the average abrasive particle size is too small, the polishing composition may not exhibit sufficient removal rate. In contrast, if the average abrasive particle size is too large, the polishing composition may exhibit undesirable polishing performance such as, for example, poor substrate defectivity.

Accordingly, the silica abrasive (e.g., silica particles or colloidal silica particles) can have an average particle diameter of about 10 nm or more, e.g., about 15 nm or more, about 20 nm or more, about 25 nm or more, about 30 nm or more, about 35 nm or more, about 40 nm or more, about 45 nm or more, about 50 nm or more, about 60 nm or more, about 70 nm or more, or about 80 nm or more. Alternatively, or in addition, the silica abrasive can have an average particle diameter of about 200 nm or less, e.g., about 175 nm or less, about 150 nm or less, about 140 nm or less, about 130 nm or less, about 125 nm or less, about 120 nm or less, about 110 nm or less, about 100 nm or less, about 75 nm or less, about 50 nm or less, or about 40 nm or less. Thus, the silica abrasive can have an average particle diameter bounded by any two of the aforementioned endpoints. For non-spherical silica abrasive particles, the size of the particle is the diameter of the smallest sphere that encompasses the particle. The particle size of the silica abrasive particles can be measured using any suitable technique, e.g., using laser diffraction techniques. Suitable particle size measurement instruments are available from, for example, Malvern Instruments (Malvern, UK).

For example, the silica abrasive (e.g., silica particles or colloidal silica particles) can have an average transmission electron microscope (TEM) equivalent diameter of about 10 nm to about 200 nm, about 20 nm to about 200 nm, about 20 nm to about 175 nm, about 20 nm to about 150 nm, about 25 nm to about 125 nm, about 25 nm to about 100 nm, about 30 nm to about 100 nm, about 30 nm to about 75 nm, about 30 nm to about 40 nm, or about 50 nm to about 100 nm. In some embodiments, the silica abrasive has an average transmission electron microscope (TEM) equivalent diameter of about 60 nm to about 150 nm. In certain embodiments, the silica abrasive has an average transmission electron microscope (TEM) equivalent diameter of about 80 nm to about 120 nm.

The silica abrasive (e.g., silica particles or colloidal silica particles) can have any suitable surface area. The surface area of the silica abrasive particles can be measured using any suitable technique, for example, using the Brunauer-Emmet-Teller (BET) surface area. Without wishing to be bound by any particular theory, the Brunauer-Emmet-Teller (BET) theory utilizes the physical adsorption of gas molecules on a solid surfaces to provide an approximation for the specific surface area of a material. For example, the silica abrasive can have an average Brunauer-Emmet-Teller (BET) surface area of about 15 cm²/g or more, about 20 cm²/g or more, about 25 cm²/g or more, or about 30 cm²/g or more. Alternatively, or in addition, the silica abrasive can have an average Brunauer-Emmet-Teller (BET) surface area of about 100 cm²/g or less, e.g., about 75 cm²/g or less, about 60 cm²/g or less, about 50 cm²/g or less, about 45 cm²/g, or about 40 cm²/g or less. Thus, the silica abrasive can have an average Brunauer-Emmet-Teller (BET) surface area bounded by any two of the aforementioned endpoints.

For example, the silica abrasive can have an average Brunauer-Emmet-Teller (BET) surface area of about 15 cm²/g to about 100 cm²/g, about 15 cm²/g to about 75 cm²/g, about 15 cm²/g to about 60 cm²/g, about 15 cm²/g to about 50 cm²/g, about 15 cm²/g to about 45 cm²/g, about 15 cm²/g to about 40 cm²/g, about 20 cm²/g to about 100 cm²/g, about 20 cm²/g to about 75 cm²/g, about 20 cm²/g to about 60 cm²/g, about 20 cm²/g to about 50 cm²/g, about 20 cm²/g to about 45 cm²/g, about 20 cm²/g to about 40 cm²/g, about 25 cm²/g to about 100 cm²/g, about 25 cm²/g to about 75 cm²/g, about 25 cm²/g to about 60 cm²/g, about 25 cm²/g to about 50 cm²/g, about 25 cm²/g to about 45 cm²/g, about 25 cm²/g to about 40 cm²/g, about 30 cm²/g to about 100 cm²/g, about 30 cm²/g to about 75 cm²/g, about 30 cm²/g to about 60 cm²/g, about 30 cm²/g to about 50 cm²/g, about 30 cm²/g to about 45 cm²/g, or about 30 cm²/g to about 40 cm²/g. In some embodiments, the silica abrasive has an average Brunauer-Emmet-Teller (BET) surface area of about 20 cm²/g to about 60 cm²/g. In certain embodiments, the silica abrasive has an average Brunauer-Emmet-Teller (BET) surface area of about 30 cm²/g to about 45 cm²/g.

In some embodiments, the silica abrasive (e.g., colloidal silica particles) is ovular or oblong. Accordingly, the silica abrasive (e.g., colloidal silica particles) can have an average aspect ratio (i.e., a width to height ratio) of greater than one, e.g., an average aspect ratio of at least 1.1, an average aspect ratio of at least 1.2, an average aspect ratio of at least 1.25, or an average aspect ratio of at least 1.3. Alternatively, or in addition, the silica abrasive can have an average aspect ratio (i.e., a width to height ratio) of 2 or less, e.g., an average aspect ratio of 1.75 or less, an average aspect ratio of 1.5 or less, or an average aspect ratio of 1.4 or less. Thus, the silica abrasive can have an average aspect ratio bounded by any two of the aforementioned endpoints. In some embodiments, the silica abrasive has an average aspect ratio of at least 1.1. In certain embodiments, the silica abrasive has an average aspect ratio of at least 1.25.

For example, the silica abrasive (e.g., colloidal silica particles) can have an average aspect ratio (i.e., a width to height ratio) of about 1.1 to about 2, about 1.1 to about 1.75, about 1.1 to about 1.5, about 1.1 to about 1.4, about 1.2 to about 2, about 1.2 to about 1.75, about 1.2 to about 1.5, about 1.2 to about 1.4, about 1.25 to about 2, about 1.25 to about 1.75, about 1.25 to about 1.5, about 1.25 to about 1.4, about 1.3 to about 2, about 1.3 to about 1.75, about 1.3 to about 1.5, or about 1.3 to about 1.4. In some embodiments, the silica abrasive has an average aspect ratio of about 1.1 to about 1.5. In certain embodiments, the silica abrasive has an average aspect ratio of about 1.25 to about 1.5.

In some embodiments, the silica abrasive (e.g., colloidal silica particles) has (i) an average transmission electron microscope (TEM) equivalent diameter of about 60 nm to about 150 nm, (ii) an average aspect ratio of at least 1.1, and (iii) an average Brunauer-Emmet-Teller (BET) surface area of about 20 cm²/g to about 60 cm²/g. In certain embodiments, the silica abrasive has (i) an average transmission electron microscope (TEM) equivalent diameter of about 80 nm to about 120 nm, (ii) an average aspect ratio of at least 1.25, and (iii) an average Brunauer-Emmet-Teller (BET) surface area of about 30 cm²/g to about 45 cm²/g.

The silica abrasive (e.g., silica particles or colloidal silica particles) preferably are colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]<0.5). More preferably, the value of [B]−[T]/[C] is less than or equal to 0.3, and most preferably is less than or equal to 0.1.

The silica abrasive can be present in the polishing composition in any suitable amount. If the polishing composition of the invention comprises too little abrasive, the composition may not exhibit sufficient removal rate. In contrast, if the polishing composition comprises too much abrasive then the polishing composition may exhibit undesirable polishing performance and/or may not be cost effective and/or may lack stability. The polishing composition can comprise about 10 wt. % or less of the silica abrasive, e.g., about 9 wt. % or less, about 8 wt. % or less, about 7 wt. % or less, about 6 wt. % or less, about 5 wt. % or less, about 4 wt. % or less of the silica abrasive. Alternatively, or in addition, the polishing composition can comprise about 3.0 wt. % or more, about 3.5 wt. % or more, or about 4.0 wt. % or more of the silica abrasive. Thus, the polishing composition can comprise silica abrasive in an amount bounded by any two of the aforementioned endpoints, as appropriate.

For example, in some embodiments, the silica abrasive can be present in the polishing composition in an amount of about 3.0 wt. % to about 10 wt. %, about 3.0 wt. % to about 8 wt. %, about 3.0 wt. % to about 6 wt. %, about 3.0 wt. % to about 5 wt. %, about 3.5 wt. % to about 10 wt. %, about 3.5 wt. % to about 8 wt. %, about 3.5 wt. % to about 6 wt. %, about 3.5 wt. % to about 5 wt. %, about 4.0 wt. % to about 10 wt. %, about 4.0 wt. % to about 8 wt. %, about 4.0 wt. % to about 6 wt. %, about 4.0 wt. % to about 5 wt. %, about 4.5 wt. % to about 10 wt. %, about 4.5 wt. % to about 8 wt. %, about 4.5 wt. % to about 5 wt. %. In some embodiments, the polishing composition comprises about 3.0 wt. % to about 10 wt. % (e.g., about 3.5 wt. % to about 8 wt. %) silica abrasive. In certain embodiments, the polishing composition comprises about 3.0 wt. % to about 5 wt. % (e.g., about 3.5 wt. % to about 5 wt. %) silica abrasive. In other embodiments, the polishing composition comprises about 4.0 wt. % to about 10 wt. % (e.g., about 4.0 wt. % to about 8 wt. %) silica abrasive.

The chemical-mechanical polishing composition comprises a polymer having a weight average molecular weight of about 300 kDa to about 7000 kDa. For example, the polymer can have a weight average molecular weight of about 400 kDa to about 7000 kDa, e.g., about 500 kDa to about 7000 kDa, about 1000 kDa to about 7000 kDa, about 1500 kDa to about 7000 kDa, about 2000 kDa to about 7000 kDa, about 3000 kDa to about 7000 kDa, about 1000 kDa to about 6000 kDa, about 1500 kDa to about 6000 kDa, about 2000 kDa to about 6000 kDa, about 3000 kDa to about 6000 kDa, about 1000 kDa to about 5000 kDa, about 1500 kDa to about 5000 kDa, about 2000 kDa to about 5000 kDa, about 3000 kDa to about 5000 kDa, about 1000 kDa to about 4000 kDa, about 1500 kDa to about 4000 kDa, about 2000 kDa to about 4000 kDa, about 3000 kDa to about 4000 kDa. In some embodiments, the polymer has a weight average molecular weight of about 1000 kDa to about 7000 kDa. In certain embodiments, the polymer has a weight average molecular weight of about 2000 kDa to about 4000 kDa.

The polymer can have any suitable polydispersity index (PDI). For example, the polymer can have a polydispersity index of at least about 1, e.g., at least about 1.1, at least about 1.2, at least about 1.3, at least about 1.4, at least about 1.5, at least about 1.6, at least about 1.7, at least about 1.8, at least about 1.9, or at least about 2.0. In some embodiments, the polymer has a polydispersity index of at least about 1.3. In certain embodiments, the polymer has a polydispersity index of at least about 1.5.

The polymer comprises an anionic polymer, a nonionic polymer, or a combination thereof. The polymer can be any suitable structure type. For example, the polymer can be a homopolymer or a copolymer. In embodiments where the polymer is a copolymer, the copolymer can exist as an alternating copolymer, random copolymer, block copolymer, or graft copolymer, and have any suitable number of different monomer units. For example, the copolymer can contain 2 different monomer units, 3 different monomer units, 4 different monomer units, 5 different monomer units, or 6 different monomer units. The copolymer monomer units can exist in any suitable concentration and any suitable proportion.

In some embodiments, the polymer comprises a nonionic polymer. As used herein, the term “nonionic polymer” refers to any polymer without a cationic or anionic charge at a pH of about 9 to about 12. For example, the nonionic polymer can be selected from polyalkylene oxides (e.g., polyethylene oxide (PEO) or polypropylene oxide (PPO)), polyetheramines, polyethylene oxide/polypropylene oxide copolymers, polyacrylamide, hydrophobically modified polyacrylamide, polyvinylpyrrolidone, cellulose, hydrophobically modified cellulose, siloxane polyalkyleneoxide copolymers, hydrophobically modified polyacrylate polymers, polysaccharides, hydrophobically modified polysaccharides, polystyrene, and combinations thereof. As used herein, the term “hydrophobically modified” refers to a chemical motif (e.g., an amide, an acid, an alcohol, or an amine) that has been modified to replace the hydrogen (e.g., N—H or O—H) with a C1-20 alkyl substituent. For example, the term “hydrophobically modified polyacrylate polymer” refers to a polyacrylic acid polymer where all acid moieties have been replaced with ester moieties. In preferred embodiments, the polymer comprises polyethylene oxide (PEO) or polypropylene oxide (PPO), or a combination thereof.

In some embodiments, the polymer comprises an anionic polymer. As used herein, the term “anionic polymer” refers to any polymer with an anionic charge at a pH of about 9 to about 12. For example, the anionic polymer can be any polymer (e.g., homopolymer or copolymer) comprising an anionic monomer comprising a carboxylate group, a phosphonate group, a sulfonate group, or a combination thereof. In some embodiments, the anionic polymer further comprises acrylamide, a hydrophobically modified acrylamide monomer, a hydrophobically modified acrylate monomer, or combinations thereof.

In some embodiments, the polymer comprises an anionic polymer comprising an anionic monomer selected from 2-acrylamido-2-methylpropane sulfonic acid, styrene sulfonate, 2-acrylamido-2-methylbutane sulfonic acid, [2-methyl-2-[(1-oxo-2-propenyl)amino]propyl]-phosphonic acid, maleic acid, methacrylic acid, acrylic acid, salts thereof, and combinations thereof. In certain embodiments, the polymer comprises an anionic polymer selected from carboxymethyl cellulose, a hydrophobically modified polyacrylate copolymer (e.g., a hydrophobically modified acrylate/acrylic acid copolymer), poly-2-acrylamido-2-methylpropane sulfonic acid, polystyrenesulfonate, salts thereof, and combinations thereof. In preferred embodiments, the polymer comprises a polyacrylic acid, poly 2-acrylamido-2-methylpropane sulfonic acid, an acrylic acid/2-acrylamido-2-methylpropane sulfonic acid copolymer, salts thereof, or combinations thereof.

The polishing composition can comprise any suitable amount of the polymer. The polishing composition can comprise about 25 ppm or more of the polymer, e.g., about 50 ppm or more, about 100 ppm or more, or about 200 ppm or more. Alternatively, or in addition, the polishing composition can comprise about 5000 ppm or less of the polymer, e.g., about 4000 ppm or less, about 3000 ppm or less, about 2000 ppm or less, or about 1000 ppm or less. Thus, the polishing composition can comprise the polymer in an amount bounded by any two of the aforementioned endpoints. For example, the polishing composition can comprise about 25 ppm to about 5000 ppm of the polymer, e.g., about 25 ppm to about 4000 ppm, about 25 ppm to about 3000 ppm, about 25 ppm to about 2000 ppm, about 25 ppm to about 1000 ppm, about 50 ppm to about 5000 ppm, about 50 ppm to about 4000 ppm, about 50 ppm to about 3000 ppm, about 50 ppm to about 2000 ppm, about 50 ppm to about 1000 ppm, about 100 ppm to about 5000 ppm, or about 100 ppm to about 1000 ppm. In some embodiments, the polishing composition comprises about 50 ppm to about 5000 ppm of the polymer. In certain embodiments, the polishing composition comprises about 100 ppm to about 2000 ppm of the polymer.

The polishing composition comprises an aqueous carrier. The aqueous carrier comprises water (e.g., deionized water) and may contain one or more water-miscible organic solvents. Examples of organic solvents that can be used include alcohols such as propenyl alcohol, isopropyl alcohol, ethanol, 1-propanol, methanol, 1-hexanol, and the like; aldehydes such as acetylaldehyde and the like; ketones such as acetone, diacetone alcohol, methyl ethyl ketone, and the like; esters such as ethyl formate, propyl formate, ethyl acetate, methyl acetate, methyl lactate, butyl lactate, ethyl lactate, and the like; ethers including sulfoxides such as dimethyl sulfoxide (DMSO), tetrahydrofuran, dioxane, diglyme, and the like; amides such as N, N-dimethylformamide, dimethylimidazolidinone, N-methylpyrrolidone, and the like; polyhydric alcohols and derivatives of the same such as ethylene glycol, glycerol, diethylene glycol, diethylene glycol monomethyl ether, and the like; and nitrogen-containing organic compounds such as acetonitrile, amylamine, isopropylamine, imidazole, dimethylamine, and the like. Preferably, the aqueous carrier is water alone, i.e., without the presence of an organic solvent.

The polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition. Typically, the chemical-mechanical polishing composition has a pH of about 9 to about 12 at the point-of-use (e.g., a pH of about 9.5 to about 12, about 10 to about 12, about 10.5 to about 12, about 11 to about 12, about 9.5 to about 11.5, about 10 to about 11.5, about 10.5 to about 11.5, about 9.5 to about 11, about 10 to about 11, about 10.5 to about 11.5, or about 11 to about 12). In some embodiments, the polishing composition has a pH of about 9 to about 12 at the point-of-use. In certain embodiments, the polishing composition has a pH of about 10 to about 12 at the point-of-use. In other embodiments, the polishing composition has a pH of about 10 to about 11 at the point-of-use.

The compound capable of adjusting and buffering the pH can be selected from the group consisting of alkyl amines, ammonium salts, alkali metal salts, carboxylic acids, alkali metal hydroxides, alkali metal nitrates, alkali metal carbonates, alkali metal bicarbonates, borates, and mixtures thereof.

The chemical-mechanical polishing composition optionally further comprises one or more additives. Illustrative additives include conditioners, acids (e.g., sulfonic acids), complexing agents, chelating agents, biocides, scale inhibitors, and dispersants.

A biocide, when present, can be any suitable biocide and can be present in the polishing composition in any suitable amount. A suitable biocide is an isothiazolinone biocide or the like. The biocide can be present in the polishing composition at a concentration of about 1 to about 750 ppm, preferably about 20 to about 200 ppm.

The polishing composition has a viscosity of at least about 1 cPs, e.g., at least about 1.1 cPs, at least about 1.2 cPs, at least about 1.3 cPs, at least about 1.4 cPs, at least about 1.5 cPs, at least about 2 cPs, at least about 2.5 cPs, or at least about 3 cPs. In some embodiments, the polishing composition has a viscosity of at least about 1.3 cPs. In certain embodiments, for example, when a nonionic polymer is used, the polishing composition has a viscosity of at least about 1.2 cPs.

There exist multiple methods of determining viscosity of a polishing composition. As referred to herein, the viscosity measurements reflect values determined with a TA Instruments Discovery HR2 Hybrid Rheometer utilizing a steel double-walled concentric cylinders bob and cup geometry. For this instrument, the bob dimensions are; inside diameter 31.98 mm, outside diameter 35.8 mm. The cup dimensions are; inside diameter 30.21 mm, outside diameter 37.03. The inner cylinder height is 55 mm with an immersed height of 53 mm. The geometry operating gap is 2000 microns. Draw rod inertia, bob inertia, bob friction and bob rotational mapping were calibrated before each use through the TA Instruments TRIOS software version 4.1.1.33073. Samples were measured at 25° C., maintained by a Peltier heating jacket through the TRIOS software.

Measurements were done by loading fourteen grams of slurry to be tested into the outer cylinder of the cup using a disposable pipet, and the cup was then placed into the heating jacket preset to 25° C. The cylinder bob was attached to the draw rod and gap height set to the operating gap of 2000 microns.

Experimental procedure for each sample was set to a 120 second temperature soak, followed by a logarithmic shear rate sweep with 5 points per decade from 10 l/s to 100 l/s. Immediately after completion of a first sweep, a second shear rate sweep was set to automatically start on the same sample following a 10 second temperature soak, sweeping logarithmically with 5 points per decade from 100 l/s to 10 l/s. Data points were collecting utilizing steady state sensing with a 60 second max equilibration time, 5 second sample period and a 5% tolerance consecutive within 3 measurements. Soft motor mode was used for the controlled rate advance. Data points from both sweeps were averaged together to get the mean average viscosity at 25 C for each sample tested. The polishing composition has a ratio of viscosity (cPs) to wt. % of silica abrasive of about 0.2 cPs/wt. % to about 1.5 cPs/wt. %, e.g., about 0.3 cPs/wt. % to about 1.5 cPs/wt. %, about 0.4 cPs/wt. % to about 1.5 cPs/wt. %, or about 0.5 cPs/wt. % to about 1.5 cPs/wt. %. In some embodiments, the polishing composition has a ratio of viscosity (cPs) to wt. % of silica abrasive of about 0.3 cPs/wt. % to about 1.5 cPs/wt. %. In certain embodiments, the polishing composition has a ratio of viscosity (cPs) to wt. % of silica abrasive of about 0.4 cPs/wt. % to about 1.5 cPs/wt. %.

The polishing composition can be produced by any suitable technique, many of which are known to those skilled in the art. The polishing composition can be prepared in a batch or continuous process. Generally, the polishing composition is prepared by combining the components of the polishing composition. The term “component” as used herein includes individual ingredients (e.g., abrasive, polymer, and/or any other optional additive) as well as any combination of ingredients (e.g., abrasive, polymer, and/or any other optional additive, etc.).

For example, the polishing composition can be prepared by (i) providing all or a portion of the liquid carrier, (ii) dispersing the abrasive, polymer, and/or any other optional additive, using any suitable means for preparing such a dispersion, (iii) adjusting the pH of the dispersion as appropriate, and (iv) optionally adding suitable amounts of any other optional components and/or additives to the mixture.

The polishing composition can be supplied as a one-package system comprising abrasive, polymer, any other optional additive, and water. Alternatively, the polishing composition of the invention can be supplied as a two-package system comprising an abrasive slurry in a first package and an additive solution in a second package, wherein the abrasive slurry consists essentially of, or consists of, abrasive particles, and water, and wherein the additive solution consists essentially of, or consists of, polymer and/or any other optional additive. The two-package system allows for the adjustment of polishing composition characteristics by changing the blending ratio of the two packages, i.e., the abrasive slurry and the additive solution.

Various methods can be employed to utilize such a two-package polishing system. For example, the abrasive slurry and additive solution can be delivered to the polishing table by different pipes that are joined and connected at the outlet of supply piping. The abrasive slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high-pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the abrasive, polymer, and/or any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component. Furthermore, as will be understood by those of ordinary skill in the art, the concentrate can contain an appropriate fraction of the water present in the final polishing composition in order to ensure that the abrasive particles, polymer, and/or any other optional additive are at least partially or fully dissolved in the concentrate.

The invention further provides a method of chemically-mechanically polishing a substrate comprising: (i) providing a substrate, (ii) providing a polishing pad, (iii) providing a chemical-mechanical polishing composition comprising: (a) about 2.5 wt. % to about 10 wt. % silica abrasive; (b) an anionic polymer having a weight average molecular weight of about 400 kDa to about 7,000 kDa; and (c) water, wherein the polishing composition has a viscosity of at least about 1 cPs, and a ratio of viscosity (cPs) to wt. % of silica abrasive of about 0.2 cPs/wt. % to about 1.5 cPs/wt. %, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of a low dielectric material. Suitable substrates include wafers used in the semiconductor industry. The wafers typically comprise or consist of, for example, a metal, metal oxide, metal nitride, metal composite, metal alloy, or combinations thereof. The method of the invention is particularly useful for polishing substrates comprising silicon oxide and/or polysilicon, e.g., any one or all of the aforementioned materials. In some embodiments, the substrate comprises silicon oxide and polysilicon on a surface of the substrate, and at least a portion of the silicon oxide and/or polysilicon on a surface of the substrate is abraded to polish the substrate.

In some embodiments, the substrate comprises silicon oxide, silicon nitride, polysilicon, or combinations thereof. The polysilicon can be any suitable polysilicon, many of which are known in the art. The polysilicon can have any suitable phase, and can be amorphous, crystalline, or a combination thereof. The silicon nitride can be any suitable silicon nitride, many of which are known in the art. The silicon nitride can have any suitable phase, and can be amorphous, crystalline, or a combination thereof. The silicon oxide similarly can be any suitable silicon oxide, many of which are known in the art. Suitable types of silicon oxide include but are not limited to borophosphosilicate glass (BPSG), high density plasma (HDP) oxides and/or plasma-enhanced tetraethyl ortho silicate (PETEOS) and/or tetraethyl orthosilicate (TEOS), thermal oxide, and undoped silicate glass. In certain embodiments, the substrate comprises silicon oxide and polysilicon.

The chemical-mechanical polishing composition of the invention can be tailored to provide effective polishing at the desired polishing ranges selective to specific thin layer materials, while at the same time minimizing surface imperfections, defects, corrosion, erosion and the removal of stop layers. The selectivity can be controlled, to some extent, by altering the relative concentrations of the components of the polishing composition. As used herein, the term “selectivity” refers to the removal rate ratio of two different targeted materials. For example, the selectivity can refer to the removal rate ratios of two different materials or the removal rate ratios of two different topographies (e.g., blanket removal vs. active removal).

In some embodiments, the chemical-mechanical polishing composition comprising: (a) about 3 wt. % to about 10 wt. % silica abrasive and (b) an anionic polymer having a weight average molecular weight of about 400 kDa to about 7,000 kDa, provides a silicon oxide removal rate that is at least 30% greater (e.g., at least 40% greater, at least 50% greater, at least 60% greater, at least 70% greater, or at least 80% greater) than the removal rate provided by an identical chemical-mechanical polishing composition that does not contain a polymer having a weight average molecular weight of about 400 kDa to about 7,000 kDa.

In some embodiments, the chemical-mechanical polishing composition comprising: (a) about 3 wt. % to about 10 wt. % silica abrasive and (b) an anionic polymer having a weight average molecular weight of about 400 kDa to about 7,000 kDa, provides a polysilicon removal rate that is at least 30% greater (e.g., at least 40% greater, at least 50% greater, at least 60% greater, at least 70% greater, or at least 80% greater) than the removal rate provided by an identical chemical-mechanical polishing composition that does not contain a polymer having a weight average molecular weight of about 400 kDa to about 7,000 kDa.

In some embodiments, the chemical-mechanical polishing composition comprising: (a) about 3 wt. % to about 10 wt. % silica abrasive and (b) an anionic polymer having a weight average molecular weight of about 400 kDa to about 7,000 kDa, provides a silicon nitride removal rate that is at least 30% greater (e.g., at least 40% greater, at least 50% greater, at least 60% greater, at least 70% greater, or at least 80% greater) than the removal rate provided by an identical chemical-mechanical polishing composition that does not contain a polymer having a weight average molecular weight of about 400 kDa to about 7,000 kDa.

In some embodiments, the chemical-mechanical polishing composition comprising: (a) about 3 wt. % to about 10 wt. % silica abrasive and (b) an anionic polymer having a weight average molecular weight of about 400 kDa to about 7,000 kDa, provides a borophosphosilicate glass removal rate that is at least 30% greater (e.g., at least 40% greater, at least 50% greater, at least 60% greater, at least 70% greater, or at least 80% greater) than the removal rate provided by an identical chemical-mechanical polishing composition that does not contain a polymer having a weight average molecular weight of about 400 kDa to about 7,000 kDa.

The polishing composition of the invention desirably exhibits low particle defects when polishing a substrate, as determined by suitable techniques. In a preferred embodiment, the chemical-mechanical polishing composition of the invention comprises a wet-process ceria which contributes to the low defectivity. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

A substrate (e.g., silicon oxide, silicon nitride, polysilicon, or a combination thereof), especially silicon comprising silicon oxide and/or polysilicon, polished with the inventive polishing composition desirably has a DCN value of about 20,000 counts or less, for example, about 17,500 counts or less, about 15,000 counts or less, about 12,500 counts or less, about 3500 counts or less, about 3000 counts or less, about 2500 counts or less, about 2000 counts or less, about 1500 counts or less, or about 1000 counts or less. Preferably substrates polished in accordance with an embodiment of the invention have a DCN value of about 750 counts or less, for example, about 500 counts or less, about 250 counts or less, about 125 counts or less, or even about 100 counts or less.

Alternatively, or in addition, a substrate polished with the chemical-mechanical polishing composition of the invention desirably exhibits low scratches as determined by suitable techniques. For example, silicon wafers polished in accordance with an embodiment of the invention desirably have about 250 scratches or less, or about 125 scratches or less, as determined by any suitable method known in the art such as, e.g., laser light scattering techniques.

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof. Soft polyurethane polishing pads are particularly useful in conjunction with the inventive polishing method. Typical pads include but are not limited to SURFIN™ 000, SURFIN™ SSW1, SPM3100 Eminess Technologies), POLITEX™ commercially available from Dow Chemical Company (Newark, Del.), and POLYPAS™ 27 commercially available from Fujibo (Osaka, JP), and EPIC™ D100 pads or NEXPLANAR™ E6088 commercially available from Cabot Microelectronics (Aurora, Ill.). A preferred polishing pad is the rigid, microporous polyurethane pad (IC1010 ™) commercially available from Dow Chemical.

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511, 5,643,046, 5,658,183, 5,730,642, 5,838,447, 5,872,633, 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

### EMBODIMENTS

(1) In embodiment (1) is presented a chemical-mechanical polishing composition comprising:
(a) about 3.0 wt. % to about 10 wt. % silica abrasive;
(b) an anionic polymer having a weight average molecular weight of about 400 kDa to about 7,000 kDa; and
(c) water, wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12.
(2) In embodiment (2) is presented the polishing composition of embodiment 1, wherein the polishing composition comprises about 3.5 wt. % to about 8 wt. % silica abrasive.
(3) In embodiment (3) is presented the polishing composition of embodiment 1 or embodiment 2, wherein the polishing composition comprises about 3.5 wt. % to about 5 wt. % silica abrasive.
(4) In embodiment (4) is presented the polishing composition of any one of embodiments 1-3, wherein the polishing composition has a pH of about 10 to about 12.
(5) In embodiment (5) is presented the polishing composition of any one of embodiments 1-4, wherein the polishing composition has a pH of about 10 to about 11.
(6) In embodiment (6) is presented the polishing composition of any one of embodiments 1-5, wherein the polishing composition has a viscosity of at least about 1.3 cPs.
(7) In embodiment (7) is presented the polishing composition of any one of embodiments 1-6, wherein the polishing composition has a viscosity of at least about 2 cPs.
(8) In embodiment (8) is presented the polishing composition of any one of embodiments 1-7, wherein the polishing composition has a ratio of viscosity (cPs) to wt. % of silica abrasive of about 0.3 cPs/wt. % to about 1.5 cPs/wt. %.
(9) In embodiment (9) is presented the polishing composition of any one of embodiments 1-8, wherein the polishing composition has a ratio of viscosity (cPs) to wt. % of silica abrasive of about 0.4 cPs/wt. % to about 1.5 cPs/wt. %.
(10) In embodiment (10) is presented the polishing composition of any one of embodiments 1-9, wherein the polymer has a weight average molecular weight of about 1000 kDa to about 7000 kDa.
(11) In embodiment (11) is presented the polishing composition of any one of embodiments 1-10, wherein the polymer has a weight average molecular weight of about 2000 kDa to about 4000 kDa.
(12) In embodiment (12) is presented the polishing composition of any one of embodiments 1-11, wherein the polymer comprises an anionic polymer comprising an anionic monomer comprising a carboxylate group, a phosphonate group, a sulfonate group, or combinations thereof
(13) In embodiment (13) is presented the polishing composition of any one of embodiments 1-12, wherein the polymer comprises an anionic polymer comprising an anionic monomer selected from 2-acrylamido-2-methylpropane sulfonic acid, styrene sulfonate, 2-acrylamido-2-methylbutane sulfonic acid, [2-methyl-2-[(1-oxo-2-propenyl)amino]propyl]-phosphonic acid, maleic acid, methacrylic acid, acrylic acid, salts thereof, and combinations thereof
(14) In embodiment (14) is presented the polishing composition of any one of embodiments 1-13, wherein the polymer comprises an anionic polymer selected from carboxymethyl cellulose, a hydrophobically modified polyacrylate copolymer, poly acrylamido-2-methylpropane sulfonic acid, polystyrenesulfonate, salts thereof, and combinations thereof
(15) In embodiment (15) is presented the polishing composition of any one of embodiments 1-14, wherein the polishing composition comprises about 50 ppm to about 5000 ppm of the polymer.
(16) In embodiment (16) is presented the polishing composition of any one of embodiments 1-15, wherein the polishing composition comprises about 100 ppm to about 2000 ppm of the polymer.
(17) In embodiment (17) is presented the polishing composition of any one of embodiments 1-16, wherein the silica abrasive has an average transmission electron microscope (TEM) equivalent diameter of about 60 nm to about 150 nm.
(18) In embodiment (18) is presented the polishing composition of any one of embodiments 1-17, wherein the silica abrasive has an average transmission electron microscope (TEM) equivalent diameter of about 80 nm to about 120 nm.
(19) In embodiment (19) is presented the polishing composition of any one of embodiments 1-18, wherein the silica abrasive has an average aspect ratio of at least 1.1.
(20) In embodiment (20) is presented the polishing composition of any one of embodiments 1-19, wherein the silica abrasive has an average aspect ratio of at least 1.25.
(21) In embodiment (21) is presented the polishing composition of any one of embodiments 1-20, wherein the silica abrasive has an average Brunauer-Emmet-Teller (BET) surface area of about 20 cm²/g to about 60 cm²/g.
(22) In embodiment (22) is presented the polishing composition of any one of embodiments 1-21, wherein the silica abrasive has an average Brunauer-Emmet-Teller (BET) surface area of about 30 cm²/g to about 45 cm²/g.
(23) In embodiment (23) is presented the The polishing composition of any one of embodiments 1-22, wherein the silica abrasive is colloidal silica.
(24) In embodiment (24) is presented a chemical-mechanical polishing composition comprising:
(a) about 3.0 wt. % to about 10 wt. % silica abrasive;
(b) a nonionic polymer having a weight average molecular weight of about 300 kDa to about 7,000 kDa; and
(c) water, wherein the polishing composition has a viscosity of at least about 1.2 cPs, and a pH of about 9 to about 12.
(25) In embodiment (25) is presented the polishing composition of embodiment 24, wherein the nonionic polymer selected from polyalkylene oxides, polyetheramines, polyethylene oxide/polypropylene oxide copolymers, polyacrylamide, hydrophobically modified polyacrylamide, cellulose, hydrophobically modified cellulose, siloxane polyalkyleneoxide copolymers, hydrophobically modified polyacrylate polymers, polysaccharides, hydrophobically modified polysaccharides, polystyrene, and combinations thereof
(26) In embodiment (26) is presented the polishing composition of any one of embodiments 24-25, wherein the polishing composition comprises about 50 ppm to about 5000 ppm of the polymer.
(27) In embodiment (27) is presented the polishing composition of any one of embodiments 24-26, wherein the polishing composition comprises about 100 ppm to about 2000 ppm of the polymer.
(28) In embodiment (28) is presented the polishing composition of any one of embodiments 24-27, wherein the silica abrasive has an average transmission electron microscope (TEM) equivalent diameter of about 60 nm to about 150 nm.
(29) In embodiment (29) is presented the polishing composition of any one of embodiments 24-28, wherein the silica abrasive has an average transmission electron microscope (TEM) equivalent diameter of about 80 nm to about 120 nm.
(30) In embodiment (30) is presented the polishing composition of any one of embodiments 24-29, wherein the silica abrasive has an average aspect ratio of at least 1.1.
(31) In embodiment (31) is presented the polishing composition of any one of embodiments 24-30, wherein the silica abrasive has an average aspect ratio of at least 1.25.
(32) In embodiment (32) is presented the polishing composition of any one of embodiments 24-31, wherein the silica abrasive has an average Brunauer-Emmet-Teller (BET) surface area of about 20 cm²/g to about 60 cm²/g.
(33) In embodiment (33) is presented the polishing composition of any one of embodiments 24-32, wherein the silica abrasive has an average Brunauer-Emmet-Teller (BET) surface area of about 30 cm²/g to about 45 cm²/g.
(34) In embodiment (34) is presented the polishing composition of any one of embodiments 24-33, wherein the silica abrasive is colloidal silica.
(35) In embodiment (35) is presented a method of chemically-mechanically polishing a substrate comprising:
(i) providing a substrate,
(ii) providing a polishing pad,
(iii) providing a chemical-mechanical polishing composition comprising:
   (a) about 3.0 wt. % to about 10 wt. % silica abrasive;
   (b) an anionic polymer having a weight average molecular weight of about 400 kDa to about 7,000 kDa; and
   (c) water,
wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12.
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.
(36) In embodiment (36) is presented the method of embodiment 35, wherein the polishing composition comprises about 3.5 wt. % to about 8 wt. % silica abrasive.
(37) In embodiment (37) is presented the method of embodiment 35 or embodiment 36, wherein the polishing composition comprises about 3.5 wt. % to about 5 wt. % silica abrasive.
(38) In embodiment (38) is presented the method of any one of embodiments 35-37, wherein the polishing composition has a pH of about 10 to about 12.
(39) In embodiment (39) is presented the method of any one of embodiments 35-38, wherein the polishing composition has a pH of about 10 to about 11.
(40) In embodiment (40) is presented the method of any one of embodiments 35-39, wherein the polishing composition has a viscosity of at least about 1.3 cPs.
(41) In embodiment (41) is presented the method of any one of embodiments 35-40, wherein the polishing composition has a viscosity of at least about 2 cPs.
(42) In embodiment (42) is presented the method of any one of embodiments 35-41, wherein the polishing composition has a ratio of viscosity (cPs) to wt. % of silica abrasive of about 0.3 cPs/wt. % to about 1.5 cPs/wt. %.
(43) In embodiment (43) is presented the method of any one of embodiments 35-42, wherein the polishing composition has a ratio of viscosity (cPs) to wt. % of silica abrasive of about 0.4 cPs/wt. % to about 1.5 cPs/wt. %.
(44) In embodiment (44) is presented the method of any one of embodiments 35-43, wherein the polymer has a weight average molecular weight of about 1000 kDa to about 7000 kDa.
(45) In embodiment (45) is presented the method of any one of embodiments 35-44, wherein the polymer has a weight average molecular weight of about 2000 kDa to about 4000 kDa.
(46) In embodiment (46) is presented the method of any one of embodiments 35-45, wherein the polymer comprises an anionic polymer, a nonionic polymer, or a combination thereof
(47) In embodiment (47) is presented the method of any one of embodiments 35-46, wherein the polymer comprises a nonionic polymer selected from polyalkylene oxides, polyetheramines, polyethylene oxide/polypropylene oxide copolymers, polyacrylamide, hydrophobically modified polyacrylamide, polyvinylpyrrolidone, cellulose, hydrophobically modified cellulose, siloxane polyalkyleneoxide copolymers, hydrophobically modified polyacrylate polymers, polysaccharides, hydrophobically modified polysaccharides, polystyrene, and combinations thereof
(48) In embodiment (48) is presented the method of any one of embodiments 35-47, wherein the polymer comprises an anionic polymer comprising an anionic monomer comprising a carboxylate group, a phosphonate group, a sulfonate group, or combinations thereof
(49) In embodiment (49) is presented the method of any one of embodiments 35-48, wherein the polymer comprises an anionic polymer comprising an anionic monomer selected from 2-acrylamido-2-methylpropane sulfonic acid, styrene sulfonate, 2-acrylamido-2-methylbutane sulfonic acid, [2-methyl-2-[(1-oxo-2-propenyl)amino]propyl]-phosphonic acid, maleic acid, methacrylic acid, acrylic acid, salts thereof, and combinations thereof
(50) In embodiment (50) is presented the method of any one of embodiments 35-49, wherein the polymer comprises an anionic polymer selected from carboxymethyl cellulose, a hydrophobically modified polyacrylate copolymer, poly-2-acrylamido-2-methylpropane sulfonic acid, polystyrenesulfonate, salts thereof, and combinations thereof
(51) In embodiment (51) is presented the method of any one of embodiments 35-50, wherein the polishing composition comprises about 50 ppm to about 5000 ppm of the polymer.
(52) In embodiment (52) is presented the method of any one of embodiments 35-51, wherein the polishing composition comprises about 100 ppm to about 2000 ppm of the polymer.
(53) In embodiment (53) is presented the method of any one of embodiments 35-52, wherein the silica abrasive has an average transmission electron microscope (TEM) equivalent diameter of about 60 nm to about 150 nm.
(54) In embodiment (54) is presented the method of any one of embodiments 35-53, wherein the silica abrasive has an average transmission electron microscope (TEM) equivalent diameter of about 80 nm to about 120 nm.
(55) In embodiment (55) is presented the method of any one of embodiments 35-54, wherein the silica abrasive has an average aspect ratio of at least 1.1.
(56) In embodiment (56) is presented the method of any one of embodiments 35-55, wherein the silica abrasive has an average aspect ratio of at least
(57) In embodiment (57) is presented the method of any one of embodiments 35-56, wherein the silica abrasive has an average Brunauer-Emmet-Teller (BET) surface area of about 20 cm²/g to about 60 cm²/g.
(58) In embodiment (58) is presented the method of any one of embodiments 35-57, wherein the silica abrasive has an average Brunauer-Emmet-Teller (BET) surface area of about 30 cm²/g to about 45 cm²/g.
(59) In embodiment (59) is presented the method of any one of embodiments 35-58, wherein the silica abrasive is colloidal silica.
(60) In embodiment (60) is presented the method of any one of embodiments 35-59, wherein the substrate comprises silicon oxide, silicon nitride, polysilicon, or combinations thereof, and wherein at least a portion of the silicon oxide, silicon nitride, polysilicon, or combinations thereof is abraded to polish the substrate.
(61) In embodiment (61) is presented a method of chemically-mechanically polishing a substrate comprising:
(i) providing a substrate,
(ii) providing a polishing pad,
(iii) providing a chemical-mechanical polishing composition comprising:
   (a) about 3.0 wt. % to about 10 wt. % silica abrasive;
   (b) a nonionic polymer having a weight average molecular weight of about 300 kDa to about 7,000 kDa; and
   (c) water,
wherein the polishing composition has a viscosity of at least about 1.2 cPs, and a pH of about 9 to about 12.
(62) In embodiment (62) is presented the method of embodiment 61, wherein the nonionic polymer selected from polyalkylene oxides, polyetheramines, polyethylene oxide/polypropylene oxide copolymers, polyacrylamide, hydrophobically modified polyacrylamide, cellulose, hydrophobically modified cellulose, siloxane polyalkyleneoxide copolymers, hydrophobically modified polyacrylate polymers, polysaccharides, hydrophobically modified polysaccharides, polystyrene, and combinations thereof
(63) In embodiment (63) is presented the method of any one of embodiments 61-62, wherein the polishing composition comprises about 50 ppm to about 5000 ppm of the polymer.
(64) In embodiment (64) is presented the method of any one of embodiments 61-63, wherein the polishing composition comprises about 100 ppm to about 2000 ppm of the polymer.
(65) In embodiment (65) is presented the method of any one of embodiments 61-64, wherein the silica abrasive has an average transmission electron microscope (TEM) equivalent diameter of about 60 nm to about 150 nm.
(66) In embodiment (66) is presented the method of any one of embodiments 24-28, wherein the silica abrasive has an average transmission electron microscope (TEM) equivalent diameter of about 80 nm to about 120 nm.
(67) In embodiment (67) is presented the method of any one of embodiments 24-29, wherein the silica abrasive has an average aspect ratio of at least 1.1.
(68) In embodiment (68) is presented the method of any one of embodiments 24-30, wherein the silica abrasive has an average aspect ratio of at least 1.25.
(69) In embodiment (69) is presented the method of any one of embodiments 24-31, wherein the silica abrasive has an average Brunauer-Emmet-Teller (BET) surface area of about 20 cm²/g to about 60 cm²/g.
(70) In embodiment (70) is presented the method of any one of embodiments 24-32, wherein the silica abrasive has an average Brunauer-Emmet-Teller (BET) surface area of about 30 cm²/g to about 45 cm²/g.
(71) In embodiment (71) is presented the method of any one of embodiments 24-33, wherein the silica abrasive is colloidal silica.

### EXAMPLES

These following examples further illustrate the invention but, of course, should not be construed as in any way limiting its scope.

The following abbreviations are used throughout the Examples: removal rate (RR); tetraethyl orthosilicate (TEOS); silicon nitride (SiN); polysilicon (polySi); borophosphosilicate glass (BPSG); polyethylene oxide (PEO); point of use (POU); and weight average molecular weight (MW).

In the following examples, substrates TEOS (i.e., silicon oxide), SiN (i.e., silicon nitride), and/or polySi were coated on bare silicon substrates, and were polished using either a MIRRA™ (Applied Materials, Inc.) polishing tool, an AP-300™ (CTS Co., Ltd) polishing tool, a Logitech™ polishing tool (Logitech, Ltd.), or a REFLEXION™ (Applied Materials, Inc.) polishing tool. An IC1010™ polishing pad (Rohm and Haas Electronic Materials) or a NEXPLANAR™ E6088 polishing pad (Cabot Microelectronics, Aurora, Ill.) were used with identical polishing parameters for all compositions. Pads were conditioned with a 189L disk from 3M. Unless stated otherwise, standard REFLEXION™ polishing parameters are as follows: IC1010™ pad, downforce=20.68 kPa (3 psi), headspeed=110 rpm, platen speed=120 rpm, total flow rate=200 mL/min. Unless stated otherwise, standard Logitech™ polishing parameters are as follows: downforce=27.58 kPa (4.0 psi), head speed=87 rpm, platen speed=93 rpm, total flow rate=50 mL/min. Unless stated otherwise, standard AP-300™ polishing parameters are as follows: IC1010™ pad, downforce=20.68 kPa (3 psi), headspeed=110 rpm, platen speed=120 rpm, total flow rate=200 mL/min. Unless stated otherwise, standard MIRRA™ polishing parameters are as follows: IC1010™ or NEXPLANAR™ E6088 pad, downforce=27.58 kPa (4 psi), headspeed=57 rpm, platen speed=63 rpm, total flow rate=175 mL/min. Removal rates were calculated by measuring the film thickness, using spectroscopic elipsometry, and subtracting the final thickness from the initial thickness.

### Example 1

This example demonstrates the effect of the type of silica abrasive particle and a polyacrylic acid polymer having a weight average molecular weight of about 540 kDa on the removal rate of TEOS, SiN, polySi, and BPSG.

Silica Abrasive Particles A1-A8 for use in Polishing Compositions 1A-1P of this Example are set forth in Table 1.

TABLE 1
Silica Abrasive Particles

| Abrasive | Average TEM Equivalent | Average | Average BET |
|---|---|---|---|
| Particle | Diameter (nm) | Aspect Ratio | (cm²/g) |
| A1 | 66 | 1.25 | 40 |
| A2 | 108 | 1.14 | 29 |
| A3 | 110 | 1.13 | 32 |
| A4 | 91 | 1.10 | 33 |
| A5 | 82 | 1.16 | 39 |
| A6 | 59 | 1.09 | 39 |
| A7 | 64 | 1.31 | 58 |
| A8 | 100 | 1.10 | 29 |

For each of the polishing compositions containing polymer, used in this example, 540 kDa MW polyacrylic acid (PAA) was added to a colloidal silica slurry containing potassium hydroxide (KOH) and a colloidal silica abrasive selected from Silica Abrasive Particles A1-A8.

The resulting compositions were diluted at the point-of-use to provide a polishing composition containing 8 wt. % colloidal silica, 2500 ppm KOH, and 1000 ppm 540 kDa MW polyacrylic acid (PAA).

Separate blanket wafers (200 mm wafers) containing TEOS, SiN, polySi, or BPSG were polished on Mirra™ tools using a NEXPLANAR™ E6088 polishing pad at a down force of 27.6 kPa (4 psi) with Polishing Compositions 1A-1P. The dynamic light scattering (nm) and viscosity (cPs) of the composition were measured and the TEOS, SiN, polySi, and BPSG removal rates were determined, and the results are set forth in Table 2.

TABLE 2
Removal Rates as a Function of Abrasive Particles and Polymer

| | | | | | TEOS | SiN | poly Si | BPSG |
|---|---|---|---|---|---|---|---|---|
| Polishing | Abrasive | | DLS | Viscosity/wt. % | RR | RR | RR | RR |
| Composition | Particle | Polymer | (nm) | (cPs/wt. %) | (Å/min) | (Å/min) | (Å/min) | (Å/min) |
| 1A | A1 | Yes | 243.3 | 0.4 | 3260 | 1077 | 4617 | 3908 |
| 1B | A1 | No | 149 | 0.1 | 3362 | 994 | 4541 | 3323 |
| 1C | A2 | Yes | 180.6 | 0.4 | 1238 | 552 | 4345 | 1465 |
| 1D | A2 | No | 104 | 0.1 | 764 | 326 | 4469 | 863 |
| 1E | A3 | Yes | 163.9 | 0.3 | 1620 | 686 | 4327 | 2051 |
| 1F | A3 | No | 105 | 0.1 | 1099 | 437 | 4471 | 1353 |
| 1G | A4 | Yes | 160 | 0.5 | 1043 | 492 | 4111 | 1171 |
| 1H | A4 | No | 94 | 0.1 | 506 | 223 | 4399 | 585 |
| 1I | A5 | Yes | 182 | 0.5 | 1442 | 641 | >5000 | 2370 |
| 1J | A5 | No | 100 | 0.1 | 882 | 358 | 3302 | 1507 |
| 1K | A6 | Yes | 123 | 0.5 | 1220 | 590 | 3945 | 1882 |
| 1L | A6 | No | 70 | 0.1 | 709 | 320 | 2436 | 1095 |
| 1M | A7 | Yes | 219 | 0.9 | 1001 | 494 | 3981 | 2020 |
| 1N | A7 | No | 83 | 0.1 | 836 | 349 | 2584 | 1695 |
| 1O | A8 | Yes | 175 | 0.4 | 1140 | 553 | 4242 | 1917 |
| 1P | A8 | No | 106 | 0.1 | 707 | 314 | 2619 | 1159 |

As is apparent from the results set forth in Table 4, Polishing Compositions 1A, 1C, 1E, 1G, 1I, 1K, 1M, and 10, which contained 1000 ppm 540 kDa MW polyacrylic acid (PAA), generally exhibited an increased removal rate of TEOS, SiN, and BPSG relative to Polishing Compositions 1B, 1D, 1F, 1H, 1J, 1L, IN and 1P, which did not contain a polymer. These results demonstrate that a 450 kDa MW polyacrylic acid (PAA) polymer can be added to the polishing composition to increase the removal rate of TEOS, SiN, and BPSG.

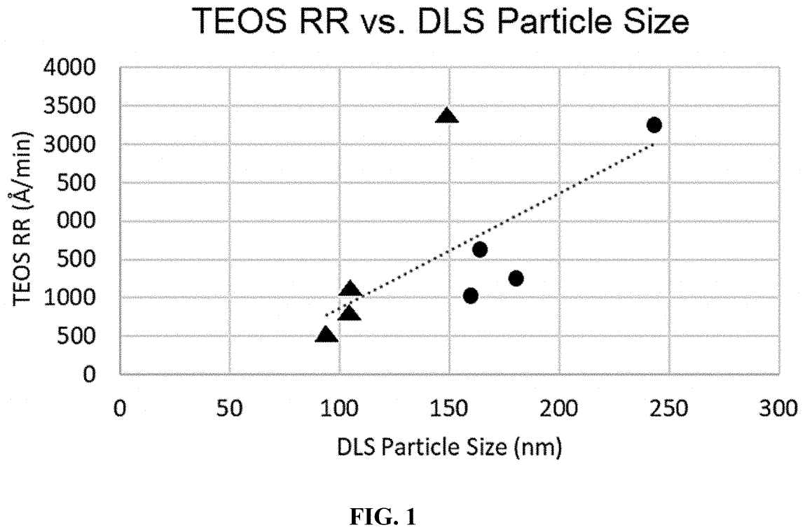

In addition, the TEOS removal rates of the polishing compositions set forth in Table 4, were plotted as a function of dynamic light scattering (DLS) particle sizes, and the results are set forth in FIG. 1. The polishing compositions without the polymer additive are plotted with a triangle and the polishing compositions with the polymer additive are plotted with a circle. FIG. 1 shows that as the DLS particle size increases, the TEOS removal rate generally increases.

### Example 2

This example demonstrates the effect of a polymer having a weight average molecular weight of about 400 kDa to about 7000 kDa on the removal rate of TEOS, SiN, and polySi.

Polymers P1-P9 for use in Polishing Compositions 2B-2R of this Example are set forth in Table 3.

TABLE 3
Polymers

| | | Polymer MW |
|---|---|---|
| Polymer | Polymer Structure | (kDa) |
| P1 | Pluronic F108 (PEG-PPG-PEG) | ~15 |
| P2 | Poly(acrylamide-co-acrylic acid) | ~400 |
| P3 | Carboxymethyl cellulose | ~780 |
| P4 | Polystyrenesulfonate | ~1725 |
| P5 | Poly(ethylene oxide) | ~700 |
| P6 | Poly AMPS | ~1000 |
| P7 | Dextran | ~1725 |
| P8 | Methacrylic acid/ethyl acrylate | 2500 |
| | copolymer | |
| P9 | Polyacrylic acid | 960 |

For each of the polishing compositions used in this example, polymers P1-P9 were added to a colloidal silica slurry containing potassium hydroxide (KOH) and a colloidal silica abrasive having an average transmission electron microscope (TEM) equivalent diameter of about 108 nm, an average aspect ratio of about 1.15, and an average Brunauer-Emmet-Teller (BET) surface area of about 29 cm²/g.

The resulting compositions were diluted at the point-of-use to provide a polishing composition containing 8 wt. % colloidal silica, 2500 ppm KOH, and the concentration of polymer provided in Table 4.

Separate blanket wafers (2×2 inch coupon wafers) containing TEOS or SiN, were polished on Logitech™ tools using a NEXPLANAR™ E6088 polishing pad at a down force of 27.6 kPa (4 psi) with Polishing Compositions 2A-2R. The viscosity (cPs) of the composition was measured and the TEOS, SiN, and polySi removal rates were determined. The results are set forth in Table 4.

TABLE 4
Removal Rates as a Function of Polymer Type

| | | Polymer | | | | |
|---|---|---|---|---|---|---|
| | | Concen- | Viscosity | TEOS | SiN | polySi |
| Polishing | Poly- | tration | (cPs/ | RR | RR | RR |
| Composition | mer | (ppm) | wt. %) | (Å/min) | (Å/min) | (Å/min) |
| 2A | — | — | 0.1 | 1433 | 463 | — |
| (Control) | | | | | | |
| 2B | P1 | 250 | 0.1 | 1245 | 468 | — |
| 2C | P1 | 500 | 0.1 | 1292 | 423 | — |
| 2D | P2 | 250 | 0.1 | 1732 | 616 | — |
| 2E | P2 | 500 | 0.1 | 1940 | 768 | — |
| 2F | P3 | 250 | 0.2 | 1860 | 748 | 6339 |
| 2G | P3 | 500 | 0.3 | 2257 | 919 | 6902 |
| 2H | P4 | 250 | 0.1 | 1406 | 630 | 5540 |
| 2I | P4 | 500 | 0.1 | 1568 | 639 | 7198 |
| 2J | P5 | 250 | 0.2 | 2618 | 866 | — |
| 2K | P5 | 500 | 0.2 | 1569 | 497 | — |
| 2L | P6 | 250 | 0.1 | 1458 | 608 | 5751 |
| 2M | P6 | 500 | 0.2 | 1625 | 701 | 5208 |
| 2N | P7 | 250 | 0.1 | 1305 | 562 | 3782 |
| 2O | P7 | 500 | 0.1 | 1402 | 558 | 3968 |
| 2P | P8 | 250 | 0.2 | 3038 | 1089 | — |
| 2Q | P8 | 500 | 0.2 | 2152 | 813 | — |
| 2R | P9 | 500 | 0.2 | 2435 | 986 | 7164 |

As is apparent from the results set forth in Table 2, Polishing Compositions, containing a polymer of the claimed invention, generally exhibited an increased removal rate of TEOS and SiN relative to control Polishing Composition 2A, which did contain not a polymer. Polishing Compositions 2J and 2K had measured viscosities of 1.2 and 1.3, respectively. In addition, Polishing Compositions 2B and 2C, containing a polymer having a weight average molecular weight of less than 400 kDa, exhibited a decreased removal rate of TEOS and SiN relative to control Polishing Composition 2A, which did not contain a polymer. These results demonstrate that polymers of the present invention can be added to the polishing composition to increase the removal rate of TEOS and SiN.

### Example 3

This example demonstrates the effect of the amount of silica abrasive and the molecular weight of the polymer on the removal rate of TEOS and SiN.

For each of the polishing compositions containing polymer, used in this example, polyacrylic acid (PAA) was added to a colloidal silica slurry containing potassium hydroxide (KOH) and a colloidal silica abrasive having an average transmission electron microscope (TEM) equivalent diameter of about 66 nm, an average aspect ratio of about 1.3, and an average Brunauer-Emmet-Teller (BET) surface area of about 40 cm²/g.

The resulting compositions were diluted at the point-of-use to provide a polishing composition containing 3 wt. % or 5 wt. % colloidal silica, 2500 ppm KOH, and 250 ppm polyacrylic acid polymer with the molecular weight designated in Table 5. Separate blanket wafers (2×2 inch coupon wafers) containing TEOS or SiN were polished on Logitech™ tools using a NEXPLANAR™ E6088 polishing pad at a down force of 20.68 kPa (3 psi) with Polishing Compositions 3A-3P. The dynamic light scattering (nm) and viscosity (cPs) of the composition were measured and the TEOS and SiN removal rates were determined, and the results are set forth in Table 5.

TABLE 5
Removal Rates as a Function of Polyacrylic Acid Molecular Weight

| | Abrasive | PAA | | | TEOS | SiN |
|---|---|---|---|---|---|---|
| Polishing | Amount | MW | DLS | Viscosity/wt. % | RR | RR |
| Composition | (wt. %) | (kDa) | (nm) | (cPs/wt. %) | (Å/min) | (Å/min) |
| 3A | 3 | — | 161 | 0.3 | 554 | 213 |
| 3B | 3 | 2 | 156 | 0.3 | 628 | 257 |
| 3C | 3 | 4 | 158 | 0.3 | 613 | 245 |
| 3D | 3 | 8.2 | 161 | 0.3 | 621 | 245 |
| 3E | 3 | 12.4 | 157 | 0.3 | 628 | 235 |
| 3F | 3 | 30 | 157 | 0.3 | 578 | 240 |
| 3G | 3 | 123 | 161 | 0.3 | 703 | 273 |
| 3H | 3 | 140 | 159 | 0.3 | 668 | 303 |
| 3I | 3 | 630 | 164 | 0.3 | 740 | 296 |
| 3J | 3 | 900 | 175 | 0.4 | 1168 | 391 |
| 3K | 3 | 1975 | 180 | 0.5 | 1130 | 503 |
| 3L | 5 | — | 155 | 0.2 | 920 | 215 |
| 3M | 5 | 140 | 161 | 0.2 | 955 | 413 |
| 3N | 5 | 630 | 180 | 0.2 | 1460 | 566 |
| 3O | 5 | 900 | 156 | 0.3 | 1773 | 651 |
| 3P | 5 | 1975 | 181 | 0.3 | 1842 | 761 |

As is apparent from the results set forth in Table 5, for polishing compositions containing 3 wt. % or 5 wt. % colloidal silica, increasing the molecular weight of the polyacrylic acid (PAA) polymer increased the removal rate of TEOS and SiN. More particularly, Polishing Compositions 3I-3K and 3N-3P, containing a PAA polymer having a weight average molecular weight of about 500 kDa to about 1250 kDa, exhibited an increased removal rate of TEOS and SiN relative to Polishing Compositions 3A-3H and 3L-3M, respectively, which did not contain a polymer or contained a PAA polymer with a weight average molecular weight of less than 250 kDa.

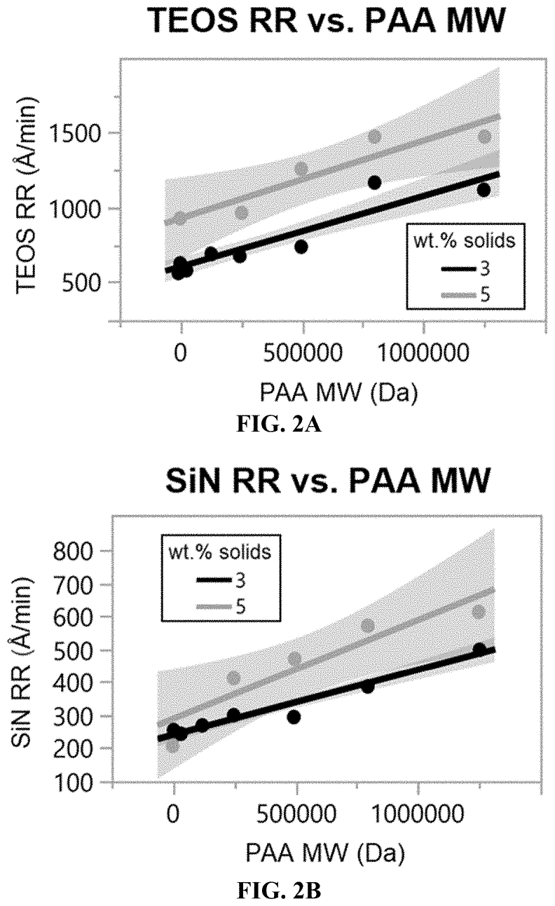

The TEOS and SiN removal rates for Polishing Compositions 3A-3P, containing 3 wt. % or 5 wt. % colloidal silica, were plotted as a function of weight average molecular weight of the PAA polymer, and the results are set forth in FIG. 2A and FIG. 2B. As is apparent from the results plotted in FIG. 2A and FIG. 2B, as the weight average molecular weight of the PAA polymer increases, the TEOS and SiN removal rates increase. These results demonstrate that a polymer having a weight average molecular weight of about 400 kDa to about 7000 kDa can be added to the polishing composition to increase the removal rate of TEOS and SiN.

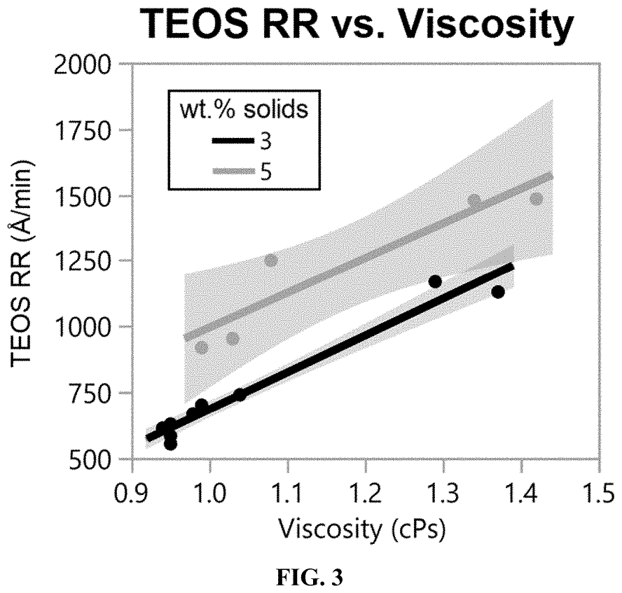

The TEOS removal rate for Polishing Compositions 3A-3P, containing 3 wt. % or 5 wt. % colloidal silica, were plotted as a function of viscosity, and the results are set forth in FIG. 3. As is apparent from the results plotted in FIG. 3, as the viscosity of the polishing composition increases, the TEOS removal rate increases.

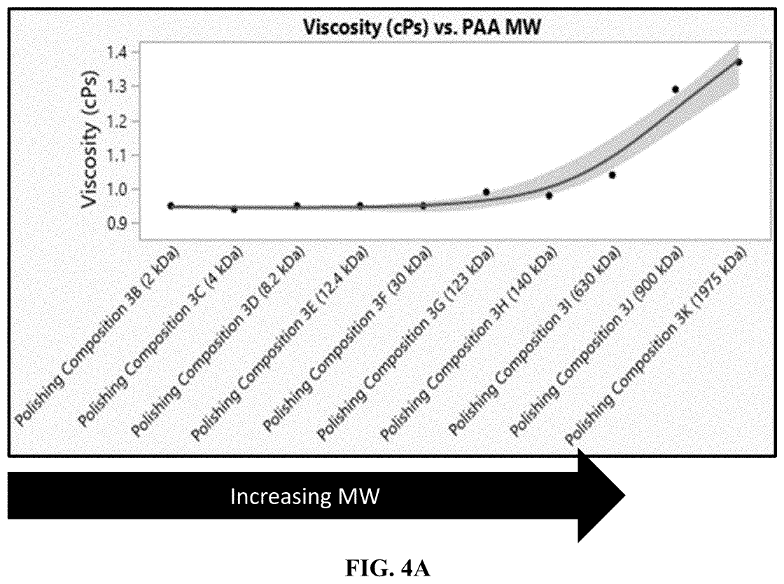

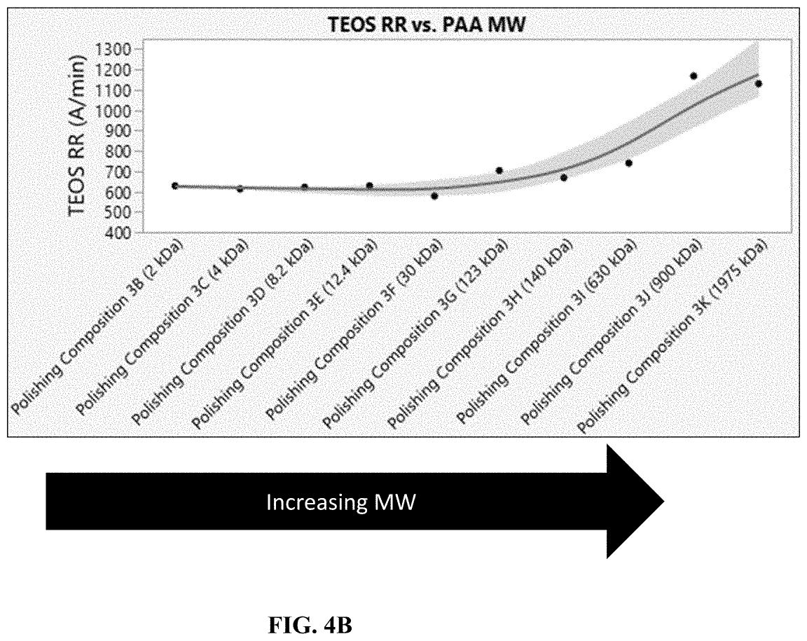

In addition, the viscosity and the TEOS removal rate for Polishing Compositions 3B-3K (noted as 6B-6K in FIGS. 4A and 4B) were plotted as a function of weight average molecular weight of the PAA polymer, and the results are set forth in FIGS. 4A and 4B, respectively. As is apparent from the results plotted in FIGS. 4A and 4B, increasing the weight average molecular weight of the PAA polymer increases the viscosity of the slurry, which in turn also increases the TEOS removal rate provided that the polishing composition has a viscosity of at least about 1 cPs and a ratio of viscosity (cPs) to wt. % of silica abrasive of about 0.2 cPs/wt. % to about 1.5 cPs/wt. %.

### Example 4

This example demonstrates the effect of the amount of silica abrasive particle on the removal rate of TEOS and SiN.

For each of the polishing compositions containing polymer, used in this example, 900 kDa MW polyacrylic acid (PAA) was added to a colloidal silica abrasive having an average transmission electron microscope (TEM) equivalent diameter of about 66 nm, an average aspect ratio of about 1.3, and an average Brunauer-Emmet-Teller (BET) surface area of about 40 cm²/g.

The resulting compositions were diluted at the point-of-use to provide a polishing composition containing 2500 ppm KOH, 250 ppm 900 kDa MW polyacrylic acid (PAA), and silica abrasive in the amount designated in Table 6.

Separate blanket wafers (2×2 in coupon wafers) containing TEOS or SiN were polished on Logitech™ tools using a NEXPLANAR™ E6088 polishing pad at a down force of 27.6 kPa (4 psi) with Polishing Compositions 6A-6N. The dynamic light scattering (nm) and viscosity (cPs) of the composition were measured and the TEOS and SiN removal rates were determined, and the results are set forth in Table 6.

TABLE 6
Removal Rates as a Function of Silica Abrasive (wt. %)

| | Abrasive | | | Viscosity/ | TEOS | SiN |
|---|---|---|---|---|---|---|
| Polishing | Amount | | DLS | wt. % | RR | RR |
| Composition | (wt. %) | Polymer | (nm) | (cPs/wt. %) | (Å/min) | (Å/min) |
| 4A | 0.1 | Yes | 170 | 0.1 | 34 | 9 |
| 4B | 0.1 | No | 150 | 0.1 | 22 | 0 |
| 4C | 0.5 | Yes | 167 | 2.5 | 114 | 29 |
| 4D | 0.5 | No | 157 | 1.8 | 85 | 8 |
| 4E | 1 | Yes | 172 | 1.24 | 296 | 96 |
| 4F | 1 | No | 153 | 0.91 | 199 | 70 |
| 4G | 2 | Yes | 173 | 0.6 | 515 | 195 |
| 4H | 2 | No | 156 | 0.5 | 414 | 155 |
| 4I | 3 | Yes | 175 | 0.4 | 1168 | 391 |
| 4J | 3 | No | 161 | 0.3 | 554 | 213 |
| 4K | 4 | Yes | 175 | 0.3 | 1119 | 427 |
| 4L | 4 | No | 164 | 0.2 | 829 | 321 |
| 4M | 5 | Yes | 156 | 0.3 | 1773 | 651 |
| 4N | 5 | No | 155 | 0.2 | 920 | 215 |

As is apparent from the results set forth in Table 6, Polishing Compositions 4I, 4K, and 4M, containing a 900 kDa MW polyacrylic acid (PAA) polymer, exhibited a significantly increased removal rate of TEOS and SiN relative to Polishing Compositions 4J, 4L, and 4N, which did not contain a polymer. These results demonstrate that an 800 kDa MW polyacrylic acid (PAA) polymer can be added to the polishing composition to increase the removal rate of TEOS and SiN.

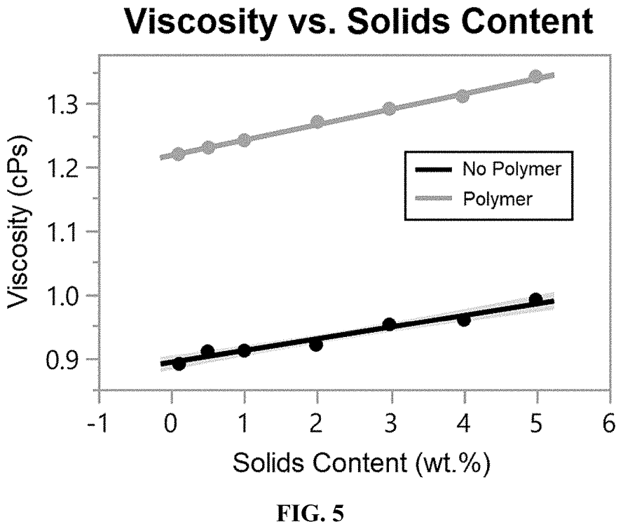

The viscosity of Polishing Compositions 4A-4N were plotted as a function of the amount of silica abrasive particle, and the results are set forth in FIG. 5. The polishing compositions without the polymer additive are plotted with a triangle and the polishing compositions with the polymer additive are plotted with a circle. FIG. 5 shows that as the amount of silica abrasive particle increases, the viscosity increases. Moreover, the addition of the 900 kDa MW polyacrylic acid (PAA) polymer drastically increases the viscosity of the polishing composition for all silica abrasive particle loadings.

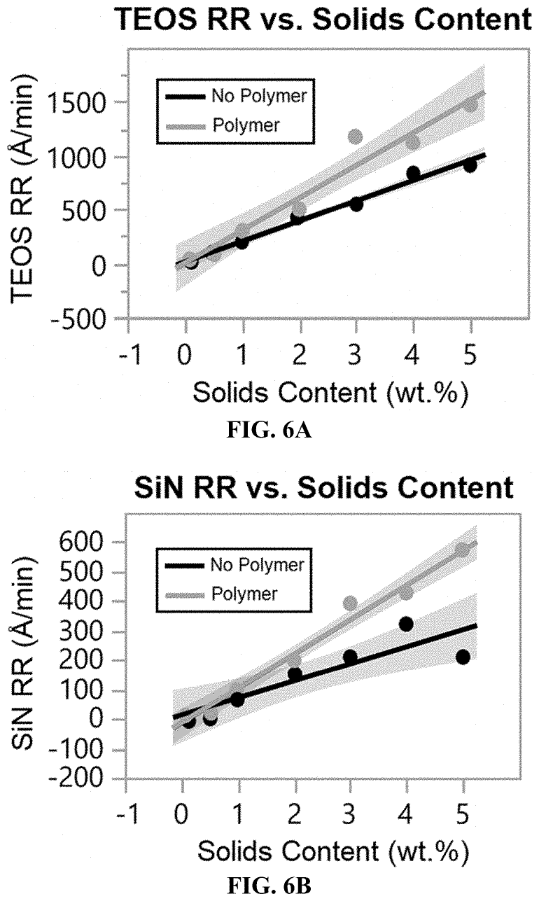

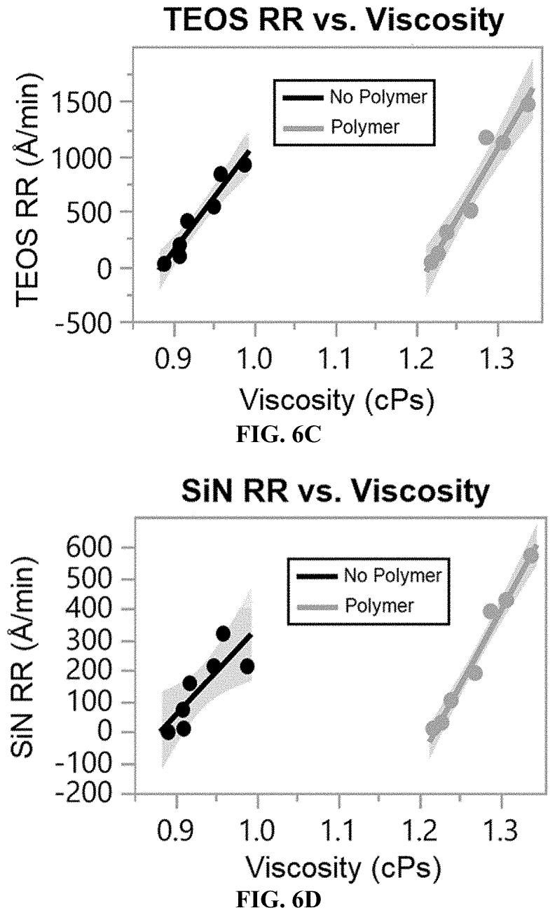

In addition, the TEOS and SiN removal rates for Polishing Compositions 4A-4N were plotted as a function of the amount of silica abrasive particle or the viscosity, and the results are set forth in FIGS. 6A-6D. The polishing compositions without the polymer additive are plotted with a triangle and the polishing compositions with the polymer additive are plotted with a circle. As is apparent from the results plotted in FIGS. 6A-6D, as the amount of silica abrasive particle and the viscosity increases, the TEOS and SiN removal rates increase. Moreover, FIGS. 6A-6D show that Polishing Compositions 4A, 4C, 4E, 4G, 4I, 4K, and 4M, containing a 900 kDa MW polyacrylic acid (PAA) polymer, generally outperformed Polishing Compositions 4B, 4D, 4F, 4H, 4J, 4L, and 4N, which did not contain a polymer, at all silica abrasive particle loadings and viscosities. Although the dramatic increase in TEOS removal rate occurred with 3 wt. % silica with the 250 ppm 800 kDa MW polyacrylic acid (PAA) polymer, other inventive polymers could be expected to lead to comparable TEOS removal rates at silica concentrations of about 3 wt. % or higher.

### Example 5

This example demonstrates the effect of the molecular weight of a nonionic polymer, and hence the increase in slurry viscosity, on the removal rate of TEOS and SiN.

Hydroxyethylcellulose (HEC) of varying molecular weights (MW) was added to an aqueous solution containing 2000 ppm (by weight) of KOH and 5 wt. % of colloidal silica, as described previously. The polymers were tested at a concentration of 500 ppm (by weight). Separate blanket wafers (2×2 in coupon wafers) containing TEOS or SiN were polished a Logitech tool using an E6088 pad, a 3M A189L conditioner, and 3 psi downforce. Viscosity (cPs) of the compositions were measured and the TEOS and SiN removal rates were determined. The results are set forth in Table 7.

TABLE 7
Removal Rates as a Function of MW of Nonionic Polymer

| | Mw by | TEOS Rate | SiN PE Rate | Average Viscosity |
|---|---|---|---|---|
| Polymer Name | GPC (Da) | (A/min) | (A/min) | (cps) |
| No Polymer | N/A | 959 ± 45 | 429 ± 31 | 0.9708 |
| Hydroxyethyl | 96000 | 914 | 388 | 1.0443 |
| Cellulose Mw | | | | |
| 90k | | | | |
| Hydroxy ethyl | 1397500 | 1374 | 604 | 2.0935 |
| Cellulose Mw | | | | |
| 1.3M | | | | |

The data in the Table 7 indicates that when a nonionic polymer (HEC) of low MW is added to the slurry (90 k MW), there is no observed impact on slurry viscosity or removal rate compared to the non-polymer containing control. However, when a nonionic polymer of high MW (HEC 1.3M MW) is added, the viscosity increases to greater than 2 cps and the TEOS removal rate increases from 959 Å/min to 1374 Å/min.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) about 3.0 wt. % to about 10 wt. % silica abrasive;
(b) an anionic polymer having a weight average molecular weight of about 400 kDa to about 7,000 kDa; and
(c) water,
wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12.

2. The polishing composition of claim 1, wherein the polishing composition comprises about 3.5 wt. % to about 8 wt. % silica abrasive.

3. The polishing composition of claim 1, wherein the polishing composition comprises about 3.5 wt. % to about 5 wt. % silica abrasive.

4. The polishing composition of claim 1, wherein the polishing composition has a pH of about 10 to about 12.

5. The polishing composition of claim 1, wherein the polishing composition has a viscosity of at least about 2 cPs.

6. The polishing composition of claim 1, wherein the polishing composition has a ratio of viscosity (cPs) to wt. % of silica abrasive of about 0.4 cPs/wt. % to about 1.5 cPs/wt. %.

7. The polishing composition of claim 1, wherein the polymer has a weight average molecular weight of about 1000 kDa to about 7000 kDa.

8. The polishing composition of claim 1, wherein the polymer has a weight average molecular weight of about 2000 kDa to about 4000 kDa.

9. The polishing composition of claim 1, wherein the polymer comprises an anionic polymer comprising an anionic monomer comprising a carboxylate group, a phosphonate group, a sulfonate group, or combinations thereof.

10. The polishing composition of claim 1, wherein the polymer comprises an anionic polymer comprising an anionic monomer selected from 2-acrylamido-2-methylpropane sulfonic acid, styrene sulfonate, 2-acrylamido-2-methylbutane sulfonic acid, [2-methyl-2-[(1-oxo-2-propenyl)amino]propyl]-phosphonic acid, maleic acid, methacrylic acid, acrylic acid, salts thereof, and combinations thereof.

11. The polishing composition of claim 1, wherein the polymer comprises an anionic polymer selected from carboxymethyl cellulose, a hydrophobically modified polyacrylate copolymer, poly-2-acrylamido-2-methylpropane sulfonic acid, polystyrenesulfonate, salts thereof, and combinations thereof.

12. The polishing composition of claim 1, wherein the polishing composition comprises about 100 ppm to about 2000 ppm of the polymer.

13. The polishing composition of claim 1, wherein the silica abrasive has an average transmission electron microscope (TEM) equivalent diameter of about 60 nm to about 150 nm.

14. The polishing composition of claim 1, wherein the silica abrasive has an average transmission electron microscope (TEM) equivalent diameter of about 80 nm to about 120 nm.

15. The polishing composition of claim 1, wherein the silica abrasive has an average aspect ratio of at least 1.1.

16. The polishing composition of claim 1, wherein the silica abrasive has an average aspect ratio of at least 1.25.

17. The polishing composition of claim 1, wherein the silica abrasive has an average Brunauer-Emmet-Teller (BET) surface area of about 20 cm²/g to about 60 cm²/g.

18. The polishing composition of claim 1, wherein the silica abrasive has an average Brunauer-Emmet-Teller (BET) surface area of about 30 cm²/g to about 45 cm²/g.

19. A chemical-mechanical polishing composition comprising:
(a) about 3.0 wt. % to about 10 wt. % silica abrasive;
(b) a nonionic polymer having a weight average molecular weight of about 300 kDa to about 7,000 kDa; and
(c) water,
wherein the polishing composition has a viscosity of at least about 1.2 cPs, and a pH of about 9 to about 12.

20. The polishing composition of claim 19, wherein the nonionic polymer selected from polyalkylene oxides, polyetheramines, polyethylene oxide/polypropylene oxide copolymers, polyacrylamide, hydrophobically modified polyacrylamide, cellulose, hydrophobically modified cellulose, siloxane polyalkyleneoxide copolymers, hydrophobically modified polyacrylate polymers, polysaccharides, hydrophobically modified polysaccharides, polystyrene, and combinations thereof.

21. A method of chemically-mechanically polishing a substrate comprising:
(i) providing a substrate,
(ii) providing a polishing pad,
(iii) providing a chemical-mechanical polishing composition comprising:
(a) about 3.0 wt. % to about 10 wt. % silica abrasive;
(b) an anionic polymer having a weight average molecular weight of about 400 kDa to about 7,000 kDa; and
(c) water,
wherein the polishing composition has a viscosity of at least about 1 cPs, a ratio of viscosity (cPs) to wt. % of silica abrasive of about 0.2 cPs/wt. % to about 1.5 cPs/wt. %, and a pH of about 9 to about 12,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

22. A method of chemically-mechanically polishing a substrate comprising:
(i) providing a substrate,
(ii) providing a polishing pad,
(iii) providing a chemical-mechanical polishing composition comprising:
(a) about 3.0 wt. % to about 10 wt. % silica abrasive;
(b) a nonionic polymer having a weight average molecular weight of about 300 kDa to about 7,000 kDa; and
(c) water,
wherein the polishing composition has a viscosity of at least about 1.2 cPs, and a pH of about 9 to about 12.
